(19) United States
(12) Patent Application Publication
(10) Pub. No.: US 2007/0222008 A1
(43) Pub. Date: Sep. 27, 2007

(54) METHOD FOR MANUFACTURING PLASTIC PACKAGING OF MEMS DEVICES AND STRUCTURE THEREOF

(75) Inventors: Jung-Tai Chen, Chu-Tung (TW); Wen-Yang Chang, Chu-Tung (TW); Yii-Tay Chiou, Chu-Tung (TW); Chun-Hsun Chu, Chu-Tung (TW)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(73) Assignee: INDUSTRIAL TECHNOLOGY RESEARCH INSTITUTE, Chu-Tung (TW)

(21) Appl. No.: 11/616,766

(22) Filed: Dec. 27, 2006

(30) Foreign Application Priority Data
Mar. 22, 2006 (TW) 095109928

(51) Int. Cl. H01L 29/84; H01L 21/00

(52) U.S. Cl. 257/415; 438/50; 438/51; 257/419

(57) ABSTRACT

A plastic packaging of MEMS device and a method therefore are provided. The method includes the steps of: provide a carrier having a surface; provide at least one MEMS device having an active surface with a sensitive area and bonding pads thereon and a back surface; proceed a photoresist process to form a sacrificial layer on the sensitive area; bind and electrically connect the MEMS device to the surface of the carrier; form at least one molding compound, to which the upper surface of the sacrificial layer is exposed. Finally, decompose the sacrificial layer by a solvent to expose the MEMS device on the sensitive area, so as to let the sensitive area contact with ambient atmosphere.

### CROSS-REFERENCE TO RELATED APPLICATIONS

This non-provisional application claims priority under 35 U.S.C. § 119(a) on Patent Application No(s). 095109928 filed in Taiwan, R.O.C. on Mar. 22, 2006, the entire contents of which are hereby incorporated by reference.

### BACKGROUND

1. Field of Invention

The invention relates to a method for manufacturing plastic packaging of microelectromechanical systems (MEMS) devices and structure thereof, and more particularly to a method of forming a space above the sensitive area of a MEMS device in a plastic packaging and structure thereof.

2. Related Art

Regarding to the microelectromechanical system (MEMS) industry, a MEMS device naturally has attractive features in microminiaturization and integration; however, the hardly reducible cost of MEMS device limits its application.

On the other hand, a cell phone may become an information center which provides various information about daily life, such as environment temperature, moisture, a volatile organic compound (VOC), carbon monoxide, intensity of UV ray, oxygen content, nitrogen content, and so on. Therefore, a microelectro sensor mechanism must be taken and the MEMS device is the best element to be chosen. Besides, many MEMS devices have already being used in cell phones, such as a microphone, micro-gyroscope, and charge coupled device (CCD) of a digital camera, and the above mentioned MEMS devices may be integrated in a cell phone in the near future as well. Thus the MEMS devices will play an important role in the cell phones, and also they are required to be as microminiaturized as possible after packaging.

A cost estimate figures that the packaging accounts for 70 to 80% of the total cost for a MEMS device. Therefore, in order to reduce the cost of a MEMS device, researchers and engineers should focus on how to reduce the cost of the packaging.

Usually, for the purpose of the sensor mechanism of a MEMS device, the MEMS sensor has exposed to the ambient atmosphere after it has been packaged. Therefore, an opening must be established on the sensitive area of the MEMS device surface. One of the conventional plastic packaging of MEMS and MEMS devices, the structure 10 in FIG. 1A, is disclosed by U.S. Pat. No. 6,379,988. According to the method, to protect the sensitive area 12, which is on the surface of the MEMS device 11 before the mold sealing process for the MEMS device 11, a sacrificial protective layer 13 will cover the surface of the MEMS device 11 in advance. Since the sacrificial protective layer 13 will be embedded in an electrically insulating material 14 after the mold sealing process, a window must be opened above the sensitive area 12, and the process of opening the window is shown on FIG. 1B and FIG. 1C. Solutions with different acids are sprayed twice in the etching process: first, an external gasket 15 covered on the electrically insulating material 14 to confine the spray of acid. Then a first acid solution 16 is used to etch. After an appropriate time of spraying, the electrically insulating material 14, which is exposed to the strong acid, is removed to expose the sacrificial protective layer 13. Second, an option internal gasket 17 covers the first opening region of the electrically insulating material 14. A second acid solution 18 is then used to etch. After an appropriate time of spraying, the sacrificial protective layer 13 is removed to release the sensitive area 12 of the MEMS device, to be exposed to the ambient atmosphere.

However, the above method has problems. The first problem is about the process of opening a window. The process above uses an acid spraying method. Since this acid spraying method needs two different strong acids for etching, and needs two different gaskets with different shapes for defining the penetrating area to penetrate through the first layer of the electrically insulating material 14 and the second layer of the sacrificial protective layer 13, this method is complex not only because additional gaskets are required but also the parameters of the acid spraying process are difficult to control. Therefore the yield is hard to improve and the method is easy to cause safety and environmental problems. Furthermore, since the acid spraying process needs to be processed one by one, the yield rate is slow. Moreover, in order to define the wiring area, the method needs to use a sacrificial protective layer 13 to cover the surface first, which includes complex photography and etching processes that will sometimes affect the yield of the wiring process.

### SUMMARY OF INVENTION

According to the foregoing problems, the present invention provides a method for manufacturing a plastic packaging of MEMS devices and structure thereof, where gaskets are not necessary for forming a window above the sensitive area of the MEMS device, and multiple windows can be formed at the same time. Therefore, the process is simplified and the yield rate may be increased. Furthermore, a strong acid spraying process is also not necessary in the present invention, thus problems like careful control of acid spraying parameters and spraying time, environment pollution, or safety problem will not occur. In addition, according to the present invention, it will not affect the region outside the sensitive area. Therefore, chances that a short circuit between the bonding pads and the carrier occurs are rare.

To achieve the above objects, a method for manufacturing a plastic packaging of MEMS devices according to the present invention includes the following steps. A carrier is provided, which has a surface. At least one MEMS device is then provided, which has an active surface and a back surface. The active surface includes a sensitive area and several bonding pads. A photography process is then performed to form a sacrifice layer on the sensitive area. The MEMS device is bound to the carrier and electrically connected to it. Next, at least one encapsulant is formed, which has a surface at the same level as the upper surface of the sacrificial layer and exposes the upper surface of the sacrificial layer. A solvent is used to discompose the sacrificial layer in order to expose the sensitive area of the MEMS device.

The carrier above can be a printed circuit board (PCB), a lead frame, or an application-specific integrated circuit (ASIC) which binds and electrically couples to a substrate.

The surface of the encapsulant can be at the same level as the upper surface of the sacrificial layer or can further comprise a guiding tube protruding from the encapsulant, to form a guiding passage. The surface of the encapsulant can further be bound to a dustproof isolation filter to cover the sensitive area of the MEMS device.

In addition the above MEMS device can further comprise a cave on the back, and the cave can be covered by a supporting structure.

Accordingly, a plastic packaging of a MEMS device according to the invention is provided, which includes a carrier; at least one MEMS device is disposed on the carrier, having an active surface, which includes a sensitive area and bonding pads; an encapsulant, which covers the carrier, an MEMS device, and bonding pads. The encapsulant has an opening above the sensitive area, to expose the sensitive area.

A dustproof isolation filter can be bound to the encapsulant, which is above the sensitive area. The surface of the encapsulant, which corresponds to the sensitive area, further includes a guiding tube protruding from the encapsulant to form a guiding passage.

### BRIEF DESCRIPTION OF THE DRAWINGS

The present invention will become more fully understood from the detailed description given below, which is for illustration only and thus is not limitative of the present invention, wherein:

FIGS. 1A to 1C are schematic cross-section views of a conventional plastic packaging of MEMS devices of making an opening on the sensitive area of MEMS device;

FIGS. 2A to 2G are schematic cross-section views of a plastic packaging of MEMS devices according to the invention;

FIG. 3 is a schematic cross-section view of a three dimensional plastic packaging of a MEMS device according to one embodiment of the invention;

FIG. 4A is a schematic cross-section view of a three dimensional plastic packaging of a MEMS device according to another embodiment of the invention;

FIG. 4B is a schematic cross-section view of a plastic packaging of a MEMS device, which has a dustproof isolation filter according to the invention;

FIG. 5 is a schematic cross-section view of a plastic packaging of a MEMS device, which has a forming guiding out passage according to the invention; and

FIG. 6 is a schematic cross-section view of a plastic packaging of a MEMS device with a suspension sensor chip according to the invention.

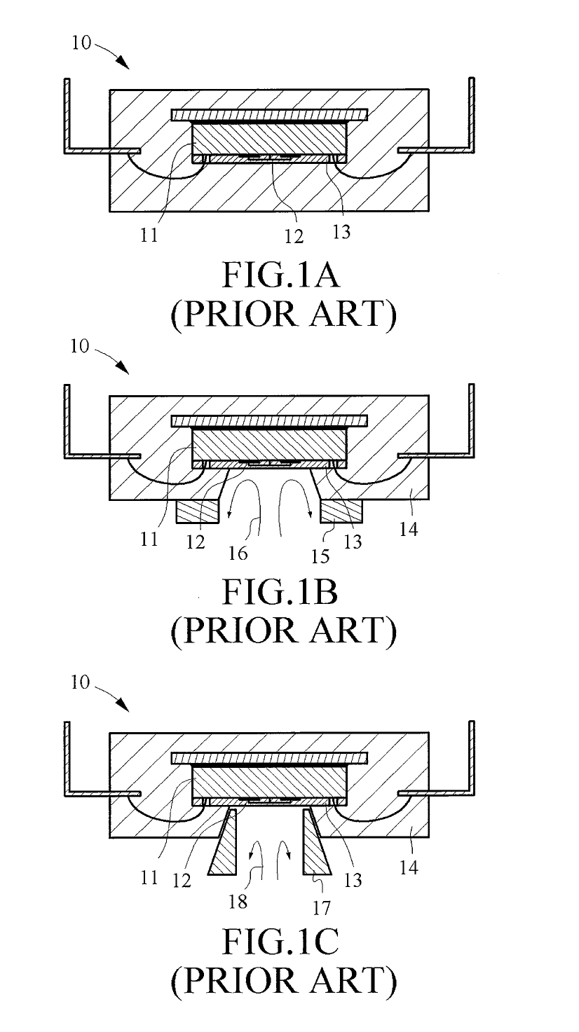

### DETAILED DESCRIPTION

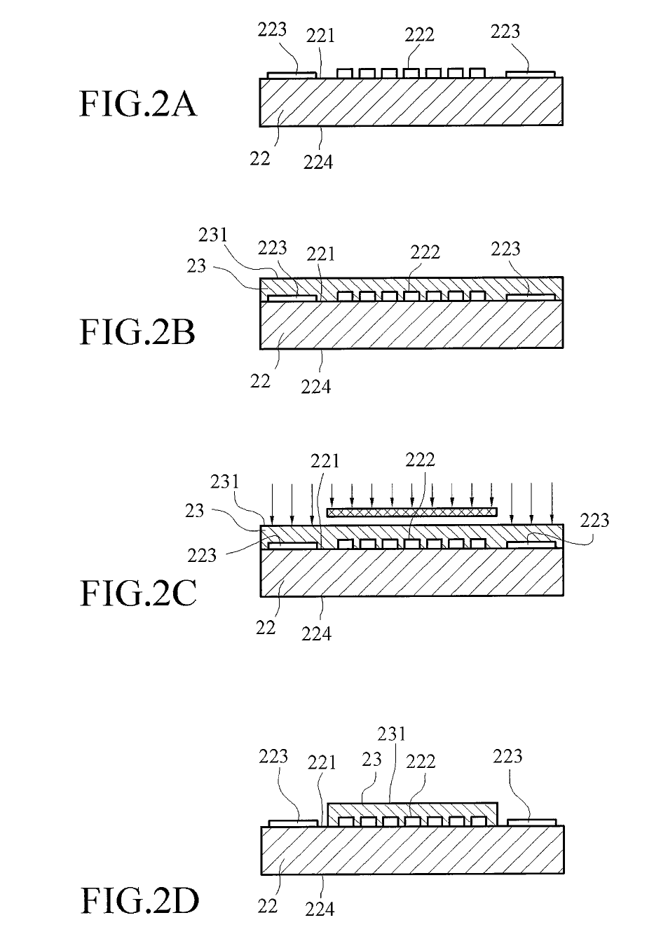

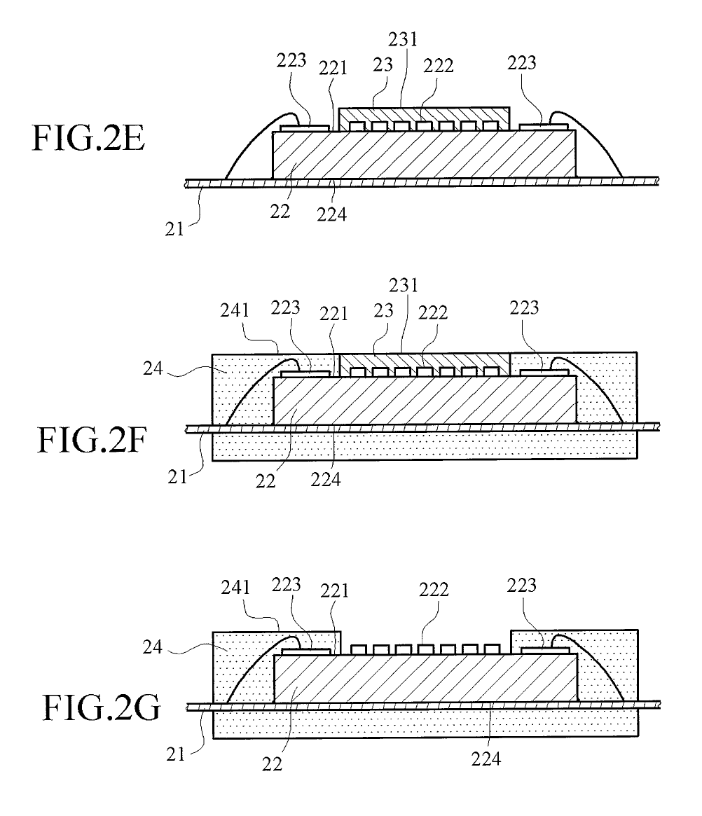

An embodiment of a method for manufacturing a plastic packaging of MEMS devices will be described with respect to FIGS. 2A to 2G First, a carrier 21, having a surface, is provided. The carrier 21 can be a PCB or a substrate, like a lead frame. Then at least one MEMS device 22 is provided, which has an active surface 221 and a back surface 224. There are a sensitive area 222 and bonding pads 223 on the active surface 221. Next, a photo-resist process is used to form a sacrifice layer 23 on the sensitive area 222 to protect the sensitive area against the follow-up encapsulating process. The sacrifice layer 23 can include a light-sensitive polymer material, such as SU-8 photoresist, and can be covered on the sensitive area 222 by spin coating, to form a uniform thickness of a photoresist layer (i.e. sacrifice layer 23), or by a screen printing process with screen mask. The back surface 224 of the MEMS device 22 is bound to the surface of the carrier 21 by Au—Sn eutectic bonding, glass gel, polymer gel or soldering, and the bonding pads 223 on the active surface 221 of the MEMS device 22 electrically connect to the carrier 21 by an electric connecting technique, such as a wire bonding process, a flip chip process or an anisotropic adhesive film process. In this embodiment, the wire bonding process is adopted. Then, at least one encapsulant 24 is formed. The encapsulant can be formed by a transfer molding process, a radial-spray coating process, or a reaction-injection molding (RIM) process. The encapsulant 24 material can be a kind of liquid drop, filled in a thermo-solidification liquid compound or a molding compound. The encapsulant 24 has a surface 241, to which the upper surface 231 of the sacrifice layer 23 is exposed. The surface 241 can be at the same level with the upper surface 231 of the sacrifice layer 23. A solvent is used to decompose the sacrifice layer 23 in order to expose the sensitive area 222 of the MEMS device to the ambient atmosphere. The solvent has characteristics which are able to remove the sacrifice layer 23 by breaking the molecular bonding instead of by a chemistry acid etching mechanism. Also, this solvent should only react to the sacrifice layer 23. Therefore, it will not erode the sensitive material and the encapsulant 24. The solvent can be an acetone solvent.

FIG. 3 shows one embodiment of a three dimensional plastic packaging of a MEMS device. The above carrier 21 can be an application-specific integrated circuit other than a printed circuit board, or a lead frame. The application-specific integrated circuit (ASIC) 25 can be disposed on a PCB or a lead frame; then the MEMS device 22 binds and electrically couples to the ASIC 25 to form an integrated three dimensional structure, in order to form a system in package (SIP) structure.

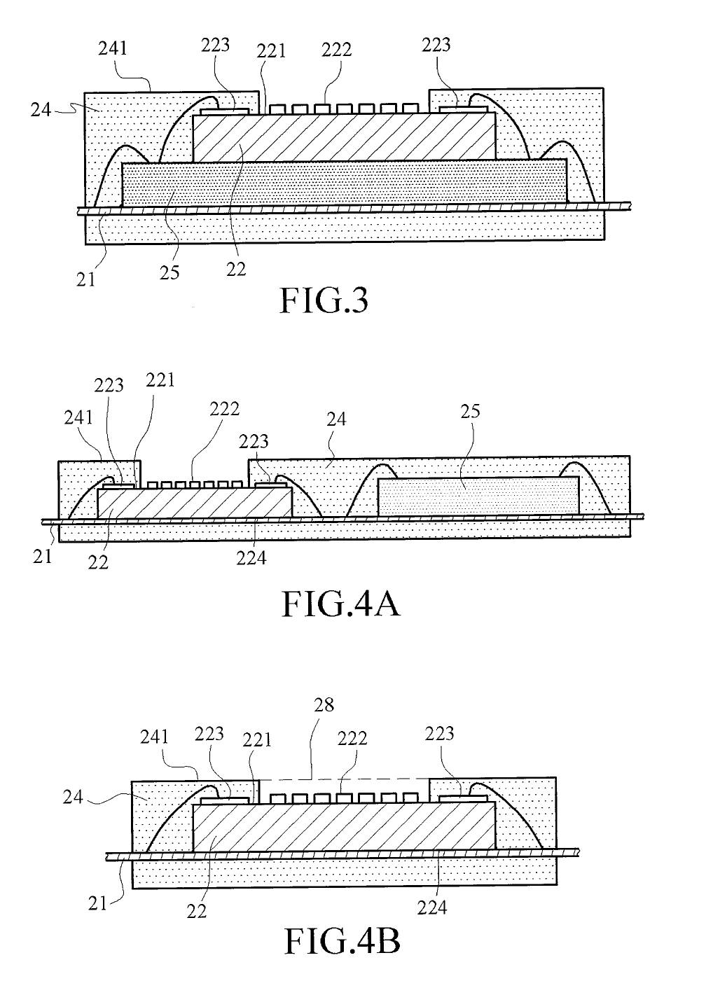

FIG. 4A shows another embodiment of a three dimensional plastic packaging of a MEMS device. The top area of the MEMS device 22 of the carrier 21 may electrically connect to an application specific integrated circuit (ASIC) 25 by a method of wire bonding or flip chip. The ASIC may be packaged inside the encapsulant 24 with the MEMS device 22.

FIG. 4B shows an embodiment of a plastic packaging of a MEMS device, which has a dustproof isolation filter. The surface 241 of the encapsulant 24 further binds to a dustproof isolation filter 28, to cover the sensitive area 222 of the MEMS device 22 for dust proofing. The material of the dustproof isolation filter 28 can be a plastic weave, a paper weave, a fiber or a metal net. It can bind to the encapsulant 24 by a hot press, sealing, or sonic vibration process.

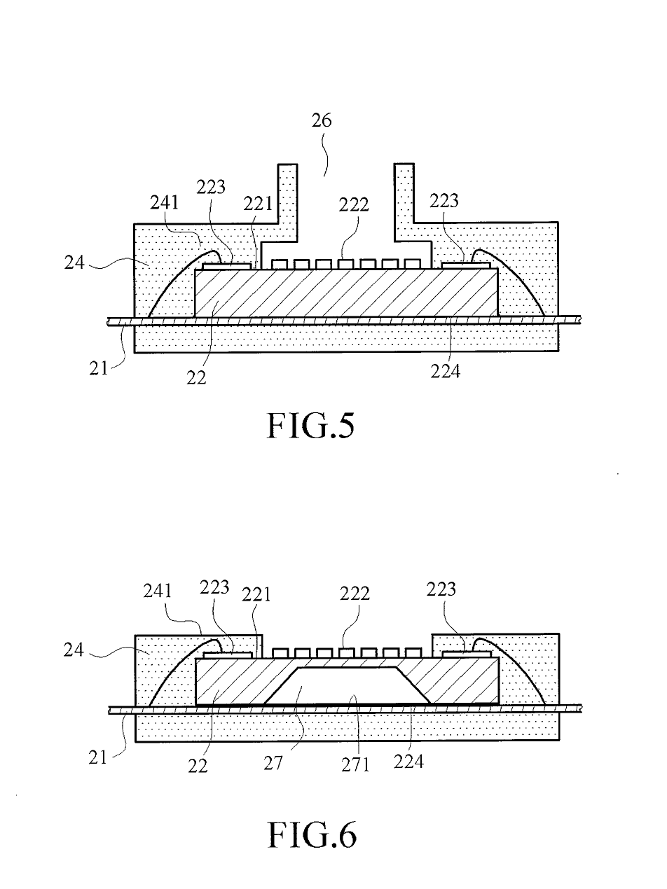

FIG. 5 shows an embodiment of a plastic packaging of a MEMS device, which has forming a guiding passage. The surface 241 of the encapsulant 24 and the upper surface 231 of the sacrifice layer 23 further include a guiding tube protruding from the encapsulant 24 to form a guiding passage 26.

FIG. 6 shows an embodiment of a plastic packaging of a MEMS device with a suspension sensor chip. The MEMS device 22 further includes a cave 27 on the back surface 224, and connects to a supporting structure layer 271 on the back surface 224, to cover the cave 27. The material of the supporting structure layer 271 is a rigid material, such as glass, a silicon wafer, metal or tempered plastic. The supporting structure layer 271 can be connected to the MEMS device by a wafer bonding, adhesive bonding or pre-molding film hot press process.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments, which do not depart from the spirit and scope of the invention.

What is claimed is:

1. A method for manufacturing plastic packaging of MEMS devices comprising the following steps of:
providing a carrier having a surface;
providing at least one microelectromechanical system (MEMS) device, which has an active surface and a back surface, the active surface including a sensitive area and a plurality of bonding pads;
performing a photoresist process to form a sacrifice layer on the sensitive area of the active surface of the MEMS device;
binding the MEMS device to a surface of the carrier, wherein the bonding pads electrically couples to the carrier;
forming at least one encapsulant to which an upper surface of the sacrificial layer is exposed; and
decomposing the sacrifice layer by a solvent to expose the sensitive area of the MEMS device.

2. The method of claim 1, wherein the surface of the carrier further comprises a plurality of packaging areas for electrically connecting to the MEMS device respectively.

3. The method of claim 1, wherein the carrier includes a printed circuit board (PCB), a lead frame, and an application specific integrated circuit (ASIC).

4. The method of claim 1, wherein the ASIC binds and electrically couples to a PCB or a lead frame.

5. The method of claim 1, wherein the carrier further includes an ASIC packaged on the encapsulant.

6. The method of claim 1, wherein a surface of the encapsulant is at the same level with an upper surface of the sacrifice layer.

7. The method of claim 1, wherein a surface of the encapsulant further comprises a guiding tube protruding from the encapsulant to form a guiding passage.

8. The method of claim 6, wherein the MEMS device further includes a cave on the back surface and connects to a supporting structure layer on the back to cover the cave.

9. The method of claim 6, wherein a surface of the encapsulant further binds to a dustproof isolation filter to cover the sensitive area.

10. The method of claim 8, wherein a surface of the encapsulant further binds to a dustproof isolation filter to cover the sensitive area.

11. The method of claim 9, wherein the surface of the encapsulant binds to the dustproof isolation filter by a hot press, adhering or sonic vibration process.

12. The method of claim 10, wherein the surface of the encapsulant binds to the dustproof isolation filter by a hot press, adhering or sonic vibration process.

13. The method of claim 9, wherein the dustproof isolation filter is a plastic weave, a paper weave, a fiber or a metal net.

14. The method of claim 10, wherein the dustproof isolation filter is a plastic weave, a paper weave, a fiber or a metal net.

15. The method of claim 8, wherein a material of the supporting structure layer is a rigid material, including glass, silicon wafer, metal or tempered plastic.

16. The method of claim 8, wherein the MEMS device binds to the supporting structure layer by a wafer bonding, adhesive bonding or pre-molding film hot press process.

17. The method of claim 1, wherein the MEMS device binds to the carrier by Au—Sn eutectic bonding, glass gel, polymer gel or soldering.

18. The method of claim 1, wherein the sacrifice layer is formed by spin coating, or screen printing.

19. The method of claim 1, wherein the sacrifice layer is SU-8 photoresist.

20. The method of claim 1, wherein the MEMS device electrically couples to the carrier by a wire bonding process, a flip chip process or an anisotropic adhesive film process

21. The method of claim 1, wherein a material of the encapsulant is a liquid drop filled in a thermo-solidification liquid compound or a molding compound.

22. A plastic packaging of MEMS devices comprising:
a carrier;
at least one MEMS device which disposes on the carrier, the MEMS having a active surface and the active surface having a sensitive area and at least one bonding pad for the MEMS; and
an encapsulant which covers the carrier, the bonding pad, and the MEMS device, the encapsulant including an opening above the sensitive area to expose the sensitive area.

23. The plastic packaging of claim 22, wherein the encapsulant binds to a dustproof isolation filter which covers the sensitive area.

24. The plastic packaging of claim 22, wherein a surface of the encapsulant which corresponds to the sensitive area further includes a guiding tube protruding from the encapsulant to form a guiding passage.
